(19) United States
(12) Patent Application Publication
(10) Pub. No.: US 2013/0143744 A1
(43) Pub. Date: Jun. 6, 2013

(54) SUPERCONDUCTING NANOWIRE AVALANCHE PHOTODETECTORS (SNAPS) WITH FAST RESET TIME

(71) Applicant: Massachusetts Institue of Technology, Cambridge, MA (US)

(72) Inventors: Francesco Marsili, Boulder, CO (US); Karl K. Berggren, Arlington, MA (US)

(73) Assignee: Massachusetts Institute of Technology, Cambridge, MA (US)

(21) Appl. No.: 13/646,439

(22) Filed: Oct. 5, 2012

Related U.S. Application Data
(60) Provisional application No. 61/544,334, filed on Oct. 7, 2011.

(51) Int. Cl. H01L 31/107; G06F 17/50; H01L 39/02

(52) U.S. Cl. CPC H01L 31/107; H01L 39/02; G06F 17/5072
USPC 505/160; 257/21; 716/122

(57) ABSTRACT

A superconducting nanowire avalanche photodetector (SNAP) with improved high-speed performance. An inductive element may be coupled in series with at least two parallel-coupled nanowires. The nanowires may number 5 or fewer, and may be superconducting and responsive to even a single photon. The series inductor may ensure current diverted from a photon-absorbing nanowire propagates to other nanowires and become amplified. The series inductance may be less than 10 times the nominal inductance per nanowire, and may also be larger than a minimum inductance to avoid spurious outputs in response to a photon absorption. The series inductance may be configured to achieve a desired tradeoff between SNAP reset time and spurious outputs. For example, the series inductance may be configured achieve minimum reset time or maximum bias margin, subject to user-defined constraints. By appropriately configuring the series inductance, a systematic method of designing improved SNAPs may be provided.

### RELATED APPLICATIONS

This application claims priority under 35 U.S.C. §119(e) to U.S. Provisional Patent Application No. 61/544334, filed Oct. 7, 2011, and entitled “OPTIMIZATION OF THE RESET TIME OF SUPERCONDUCTING NANOWIRE AVALANCHE PHOTODETECTORS (SNAPs),” which is incorporated herein by reference in its entirety for all purposes.

### GOVERNMENT SPONSORSHIP

This invention was made with government support under Grant No. DE-SC0001088 awarded by the Department of Energy. The government has certain rights in the invention.

### FIELD OF INVENTION

Systems, articles, and methods related to nanowire-based detectors are generally described.

### BACKGROUND

Photodetectors are used in a variety of detectors and sensors in systems used for communications, computing and to detect photons in astronomy and other fields. In general, photodetectors detect the arrival of photons and output an electrical signal indicative of a rate and a number of photon arrivals. In order to accurately detect photons, efforts have been made to improve the speed and efficiency of photodetectors.

The use of nanowires in photodetectors has been the subject of research. In many nanowire-based detectors, one or more nanowires are positioned on a substrate toward which photons are directed. Individual photons can couple with the nanowire(s), producing a detectable signal. Often, the nanowires are designed to be thin enough to detect a very small amount of energy (e.g., single photons).

A superconducting nanowire avalanche photodetector (SNAP, also referred to as a cascade-switching superconducting photon detector) is a device that uses at least two superconductive nanowires to amplify a signal resulting from a photon absorption. The overall amplification of a superconducting nanowire avalanche detector with N nanowires (N-SNAP) can be up to N times the amplification of the individual nanowires. SNAPs are often implemented in receivers and sensors to achieve larger signal-to-noise ratio (SNR) for decoding information from photon arrivals.

An N-SNAP generally operates based on an avalanche effect. Changes at one nanowire, when a photon interacts with it, impact other nanowires connected in parallel to it. These other nanowires also react, such that the combined reaction of the N-SNAP is greater than the reaction of any single nanowire.

To enable this avalanche operation of an N-SNAP, the total amount of bias current is typically configured to be large enough such that the partial current flowing through each of the N nanowires is near a critical current for the nanowire, allowing the nanowires to be responsive to the energy absorbed by a photon. The minimum level of bias current flowing through a nanowire that, if diverted to other parallel nanowires, will also cause those parallel nanowires to switch to a non-superconducting state, is typically called the avalanche current, or I_{AV}, of the SNAP device.

The nanowires in a SNAP are sometimes configured as superconducting nanowire single photon detectors (SNSPDs). SNSPDs are detectors that use low-temperature nanowires, each covering an area on a planar substrate. The nanowires are connected in parallel with each other and to a load resistor. By current-biasing the nanowires close to their superconducting critical current, they become very sensitive to the absorbed energy of photons. Even a single incident photon absorbed in a nanowire temporarily creates a region of non-superconductance, or “hot spot,” in the otherwise superconducting wire.

This higher resistance hot spot decreases the amount of bias current flowing through that nanowire, which has the effect of diverting more current to the other nanowires, and to the load resistor. Because those nanowires were initially biased slightly below their critical currents, the increased current exceeds the critical current, causing those nanowires to lose their superconducting properties, too. As a result, the parallel nanowires, originally highly conductive, become resistive such that the bias current is diverted to the load resistor, which has lower impedance (typically 50 Ohms). The current flowing through the load resistor produces a voltage which can be read out.

This voltage remains as long as the nanowires in all the sections of the SNAP remain in a resistive state. As the nanowires cool, they return to the superconducting state. When the entire structure returns to the superconducting state, the current is diverted from the read out resistor back to the sections of the SNAP. As the current through the load resistor decreases, the voltage decreases as well. As a result, the detector responds to a photon with a sudden increase, then a decrease in voltage, creating a voltage pulse to indicate that a photon was detected.

The voltage pulse typically has a very brief duration. It has been suggested in the art, for example, in “Characterization of superconducting pulse discriminators based on parallel NbN nanostriplines,” M. Ejrnaes et al., Superconductor Science and Technology 24, 035018 (2011), to slow down the voltage pulse for easier photon detection by connecting a large inductor, with an inductance at least 10 time the nominal inductance of the nanowires, in series with the parallel combination of nanowires.

### SUMMARY OF THE INVENTION

The inventors have recognized and appreciated techniques that may be used to improve measurement quality and/or increase efficiency in SNAPs.

Some aspects relate to a superconducting nanowire avalanche photodetector (SNAP). The SNAP may comprise at least two nanowires coupled in parallel. Each of the at least two nanowires may have a nominal inductance L₀. An inductive element may be coupled in series with the at least two nanowires, the inductive element having inductance L_{S}. Furthermore, the inductance L_{S} may be less than 10*L₀.

Some aspects relate to a method of designing a SNAP. The method may comprise receiving inputs comprising values indicating a number N of at least two nanowire to be coupled in parallel. The input may also comprise a nominal inductance L₀ of the at least two nanowires. The method may also comprise computing a value L_{S} of an inductive element to be coupled in series with the at least two nanowires. Computing the value L_{S} may be based on the number N of nanowires and the nominal inductance L₀. The value of inductance L_{S} may be less than or equal to 10*L₀.

Some aspects relate to at least one computer-readable storage medium comprising computer executable instructions that, when executed by a computing device, perform a method of designing a SNAP. The method may comprise receiving inputs comprising values indicating a number N of at least two nanowires to be coupled in parallel. The inputs may also comprise a nominal inductance L₀ of the at least two nanowires. The method may further comprise computing a value L_{S} of an inductive element to be coupled in series with the at least two nanowires. Computing the value L_{S} may be based on the number N of the at least two nanowires and the nominal inductance L₀. The value of inductance L_{S} may be less than or equal to 10*L₀.

The foregoing is a non-limiting summary of the invention. Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic illustration of an exemplary optical communication system, in accordance with some embodiments;

FIG. 2A is a schematic illustration of an exemplary configuration of a SNAP in steady-state, in accordance with some embodiments;

FIG. 2B is a schematic illustration of an example of a SNAP that has absorbed a photon and begun a first stage of an amplification process, in accordance with some alternative embodiments;

FIG. 2C is a schematic illustration of an example of a SNAP that has absorbed a photon and transitioned to a second stage of amplification, in accordance with some embodiments;

FIG. 3 is a sketch of the ratio of avalanche current to switching current as a function of series inductance for different numbers of parallel nanowires, in accordance with some embodiments;

FIG. 4 is a flow chart of an exemplary method of designing a SNAP, in accordance with some embodiments; and

FIG. 5 is a schematic illustration of a representative computing device on which some embodiments may operate.

### DETAILED DESCRIPTION

The inventors have recognized and appreciated that the value of a series inductance may impact the efficiency as well as the amount of spurious output noise and jitter in a SNAP. By recognizing multiple relationships between the value of the series inductance and performance characteristics of the SNAP, the inventors have recognized and appreciated techniques that may be applied to select a value of the series inductor to provide desirable operating characteristics in a SNAP.

The inventors have recognized and appreciated that a large series inductor may be detrimental to efficiency by slowing down the reset time of a SNAP. The efficiency of a photodetector may be measured as the ratio of the number of output pulses generated to the number of photons incident on the photodetector. A high efficiency implies that a large percentage of photons arrivals can be detected, while a low efficiency implies that many photons arrivals go undetected.

After a photon is absorbed, there is a delay, called the SNAP “reset” time T_{R}, during which the SNAP returns to steady-state and the bias current is again evenly distributed among the N nanowires. After this reset time, the SNAP is ready to detect another photon. However, if a photon arrives before the SNAP is reset, then one or more nanowires may not be able to react to that photon, and the photon arrival may go undetected or yield a weak output signal. Thus, the SNAP reset time T_{R} may affect the efficiency of a SNAP.

Because a large series inductance slows down the recovery of bias current in a SNAP after a photon detection, it impacts efficiency. As such, the inventors have recognized and appreciated techniques for reducing the SNAP reset time by reducing the series inductance. In some embodiments, the series inductance may be less than 10 times the nominal inductance L₀ of an individual nanowire.

The SNAP reset time may also be reduced by coupling together an increased number of nanowires. Such configurations may be used either in conjunction with or separately from techniques for adjusting the series inductance.

However, the inventors have recognized and appreciated reduction of the SNAP reset time below certain levels may not be practical or possible. In some embodiments, the SNAP reset time may be limited to being larger than an individual nanowire's thermal relaxation time. The thermal relaxation time represents the time for a hot spot in the nanowire to dissipate after a photon is absorbed. The inventors have recognized and appreciated that reducing the SNAP reset time below the nanowire thermal relaxation time may result in instability and/or after-pulsing, in which spurious pulses are generated for a single photon absorption. Accordingly, in some embodiments, a value of the series inductance may be selected to yield a SNAP reset time that is larger than the nanowire thermal relaxation time.

The inventors have also recognized and appreciated a relationship between the number of parallel nanowires and the SNAP reset time. In some embodiments, to avoid such instability and spurious output pulses, the number of parallel nanowires may be less than or equal to 4. In some embodiments, the number of nanowires may be less than or equal to 5. Furthermore, the series inductance may be configured to be greater than a minimum inductance, which depends on the number of nanowires and/or the nanowire thermal relaxation time.

The inventors have further recognized and appreciated that, contrary to what has been expressed in the art, the benefits of a series inductor are a result of reducing the amount of current that “leaks” from the parallel set of nanowires to the load resistor. In embodiments in which the series inductor is connected in series with the parallel combination of nanowires, but in parallel with the load resistor, the inductor tends to resist sudden changes in the total current through the parallel nanowires. When a nanowire leaves its superconducting state because of interaction with a photon, less current will flow through that nanowire. The preservation of current enforced by the series inductor means that there will be a corresponding increase in current through other nanowires. Though some of the change of current in one nanowire may be offset by some “leakage” through the load resistor, substantially all of the changed current will initially stay within the remaining parallel nanowires that are still in their superconducting states.

Thus, the series inductor may be said to substantially “trap” current in the nanowires, such that changes in current may then propagate to, and activate, adjacent nanowires. The inventors have recognized and appreciated that, by trapping the current, the SNAP may transition more quickly to a non-conducting state, producing an output pulse with less jitter in response to a photon, and that this effect may be enhanced by a larger series inductor.

Furthermore, the inventors have recognized and appreciated that a large series inductance may provide smaller avalanche currents I_{AV}, allowing larger bias margin for correct operation of the SNAP. The bias margin may reflect the difference between the avalanche current I_{AV} and a threshold critical current through a nanowire that can cause the nanowire to leave its superconducting state. A small bias margin may increase the likelihood of a spurious response from the SNAP.

Therefore, the inventors have recognized and appreciated that the series inductance may be configured to control a tradeoff between increased bias margin and reduced SNAP reset time. Because bias margin may impact spurious outputs and SNAP reset time impacts efficiency, the inventors have recognized that a value of the series inductor may be selected to provide a desirable balance between efficiency and spurious outputs. The inventors have recognized and appreciated that, in some embodiments, for a desired level of bias margin, the SNAP reset time T_{R} may be minimized by configuring the series inductance to be as small as a minimum inductance determined by the desired level of bias margin.

The inventors have recognized and appreciated that various techniques may be used, either separately or in any suitable combination, to improve the reset time and efficiency of SNAPs. For example, the SNAP may use inductive nanowire-based detectors, which can be used for detection in, for example, single-photon detectors. In some embodiments, these techniques may be used with superconducting nanowire photon detectors, such as superconducting nanowire single photon detectors (SNSPDs).

The systems, articles, and methods described herein can be used in a variety of applications, for example, to produce highly sensitive photon counters. Such counters can be useful in the production of cryptographic devices (e.g., fiber-based quantum key distribution systems), photon counting optical communication systems, and the like. In some cases, the systems, articles, and methods can be used to produce or as part of a linear optical quantum computer. The embodiments described herein can also be used in the evaluation of transistor elements in large-scale integrated circuits, as the elements emit photons; characterization of the photons and their time of arrival can be used to understand the operation of the circuit, for example. The embodiments described herein may also find use in underwater communications, inter-planetary communications, or any communication system in which ultra-long-range or absorbing or scattering media produce relatively high link losses.

In some cases, circuit components may be fabricated on a chip, and offloaded onto microwave lines for amplification and readout. Superconducting nanowire photon detectors may operate at telecom wavelengths, making them suitable for high-speed communications over long-distance telecom optical fibers.

In some cases, the methods described herein can be used with superconducting nanowire single-photon detectors (SNSPDs). The basic functionality of SNSPDs are described, for example, in “Electrothermal feedback in superconducting nanowire single-photon detectors,” Andrew J. Kerman, Joel K. W. Yang, Richard J. Molnar, Eric A. Dauler, and Karl K. Berggren, Physical Review B 79, 100509 (2009). Briefly, a plurality of photons can be directed toward a superconducting nanowire (e.g., a niobium nitride (NbN) nanowire). A portion of the photons can be absorbed by the nanowire, to which a bias current is applied. When an incident photon is absorbed by the nanowire with a bias current slightly below the critical current of the superconducting nanowire, a resistive region called hot-spot is generated, which can yield a detectable voltage pulse.

In many systems and devices employing photon-detecting nanowires (e.g., where the nanowire is being used in an SNSPD), it can be beneficial to design the nanowire such that it is narrower than 100 nm and as thin as 4 to 6 nm to allow for effective photon detection. In nanowires used to detect infrared radiation, for example, these nanowire widths are an order of magnitude narrower than the Rayleigh diffraction limit of the infrared radiation. Therefore, it is often beneficial to design the nanowire (or a plurality of nanowires) such that they cover a relatively large amount of area.

The term “electrically superconductive material,” is given its accepted meaning in the art, i.e., a material that is capable of conducting electricity in the substantial absence of electrical resistance below a threshold temperature. One of ordinary skill in the art would be able to identify electrically superconductive materials suitable for use with the invention.

The electrically superconductive material can be formed using any suitable method. In some cases, the electrically superconductive material can be provided as an as-grown film on a substrate. In some instances, the electrically superconductive material can be formed via electron-beam deposition or sputter deposition. In some embodiments, a relatively thin layer of electrically superconductive material can be provided. For example, in some embodiments, the layer of electrically superconductive material can have an average thickness of less than about 20 nm, less than about 10 nm, less than about 5 nm, between about 2 nm and about 20 nm, between about 2 nm and about 10 nm, or between about 4 nm and about 6 nm. One of ordinary skill in the art would be capable of measuring the thicknesses (and calculating average thicknesses) of thin films using, for example, a transmission-electron microscope.

A variety of electrically superconductive materials are suitable for use in the embodiments described herein. For example, in some embodiments, the electrically superconductive material can comprise niobium (Nb). In some cases the electrically superconductive material can be niobium nitride (NbN), niobium metal, niobium titanium nitride (NbTiN), or a combination of these materials. Though, it should be appreciated that the invention is not limited to a particular superconductive materials, and other suitable materials may be used, such as tungsten silicide, which is a material known in the art. In some cases, the electrically superconductive material can be patterned to form a nanowire, as discussed in more detail below. The electrically superconductive material (e.g., in the form of a nanowire) can be used, in some embodiments, as a medium in or on which photons are absorbed (e.g., when used in a photon detector).

A variety of substrates are suitable for use in the systems, articles, and methods described herein. In many embodiments, the substrate is formed of an electrically insulating material. The substrate can be capable, in some instances, of transmitting at least a portion of at least one wavelength of electromagnetic radiation. For example, the substrate might be substantially transparent to at least one wavelength of electromagnetic radiation (e.g., at least one wavelength, as measured in a vacuum, of infrared radiation). In embodiments where the nanowire is constructed and arranged to detect photons, the substrate can be formed of a material that is capable of transmitting at least a portion of the photons of a predetermined wavelength that the detector is constructed and arranged to detect. The use of a transparent substrate can allow one to employ opaque materials (e.g., metals) on the side of the detector opposite the substrate while maintaining a pathway by which photons can reach and be absorbed by the nanowire. Examples of materials suitable for use in the substrate include, but are not limited to, sapphire, magnesium oxide, silicon nitride, and silicon dioxide.

The term “nanowire,” as used herein, is used to refer to an elongated structure that, at any point along its longitudinal axis, has at least one cross-sectional dimension (as measured perpendicular to the longitudinal axis) of less than 1 micron. In some embodiments, a nanowire can have, at any point along its longitudinal axis, two orthogonal cross-sectional dimensions of less than 1 micron. An “elongated” structure is a structure for which, at any point along the longitudinal axis of the structure, the ratio of the length of the structure to the largest cross-sectional dimension perpendicular to the length at that point is greater than 2:1. This ratio is termed the “aspect ratio.” In some embodiments, the nanowire can include an aspect ratio greater than about 2:1, greater than about 5:1, greater than about 10:1, greater than about 100:1, or greater than about 1000:1.

The nanowire can have any suitable width. Generally, the width of the nanowire at a given point along the longitudinal axis of the nanowire is measured as the largest cross-sectional dimension of the nanowire parallel to the plane of the material on which the nanowire is positioned and perpendicular to the longitudinal axis of the nanowire. For example, in cases where the nanowire is positioned on or proximate a substrate, the width of the nanowire is generally measured in a direction parallel to the plane defined by the substrate. In some embodiments, the maximum width of the nanowire (i.e., the maximum of the widths along the longitudinal axis of the nanowire) can be less than about 500 nm, less than about 250 nm, less than about 100 nm, less than about 25 nm, between about 10 nm and about 500 nm, between about 25 nm and about 500 nm, between about 50 nm and about 250 nm, or between about 75 nm and about 125 nm. In some instances, the average width of the nanowire (i.e., the average of the widths as measured along the length of the nanowire) can be less than about 500 nm, less than about 250 nm, less than about 100 nm, between about 25 nm and about 500 nm, between about 50 nm and about 250 nm, or between about 75 nm and about 125 nm.

In some embodiments, the nanowire can include a relatively consistent width. For example, the width of a nanowire can be within about 20%, within about 10%, within about 5%, or within about 1% of the average width of the nanowire over at least about 50%, at least about 75%, at least about 90%, at least about 95%, or at least about 99% of the length of the longitudinal axis of the nanowire.

In some embodiments, the nanowire can include a plurality of elongated portions (whether straight or curved) that can be substantially equally spaced. In some cases, the substantially equally spaced elongated portions (whether straight or curved) can be separated by distances (as measured along a straight line perpendicular to the lengths of and/or tangents of each of the two elongated portions) that are within about 90% of the average distance between the two portions along at least about 90% of the length of the portions. In some embodiments, the distances between the two substantially equally spaced elongated portions can be within about 90%, within about 95%, or within about 99% of the average distance between the two portions along at least about 90%, along at least about 95%, or along at least about 99% of the lengths of the portions, wherein the elongated portions have aspect ratios of greater than about 5:1, greater than about 10:1, greater than about 100:1, or greater than about 1000:1. A nanowire can include, in some embodiments, at least 3, at least 4, at least 5, or more elongated portions meeting the criteria outlined above.

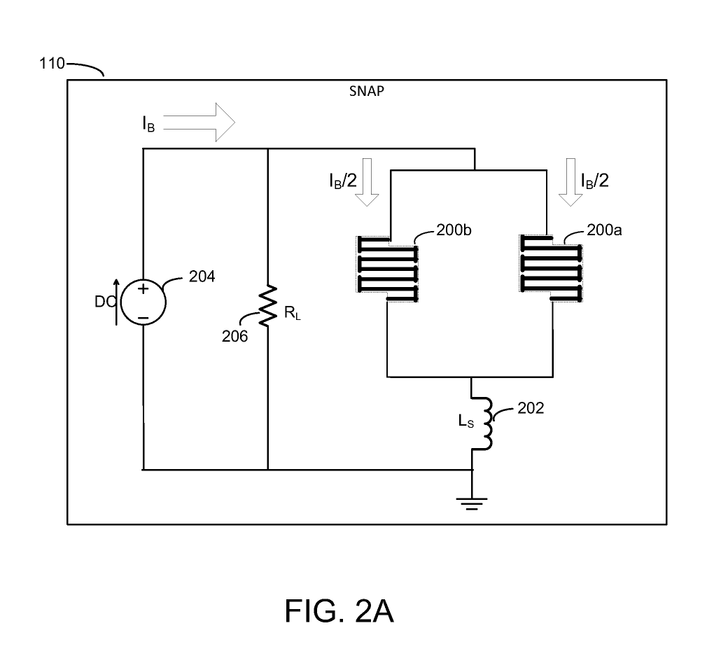

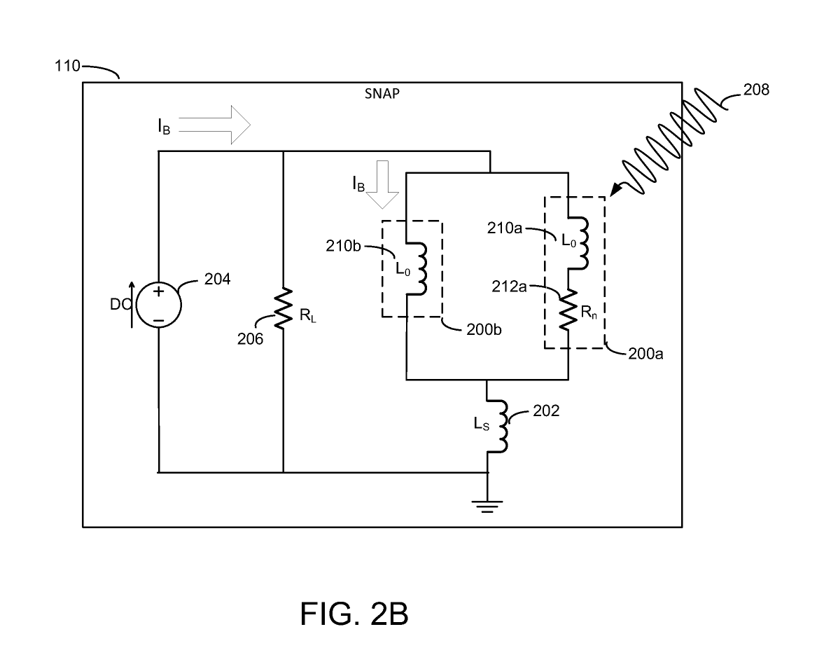

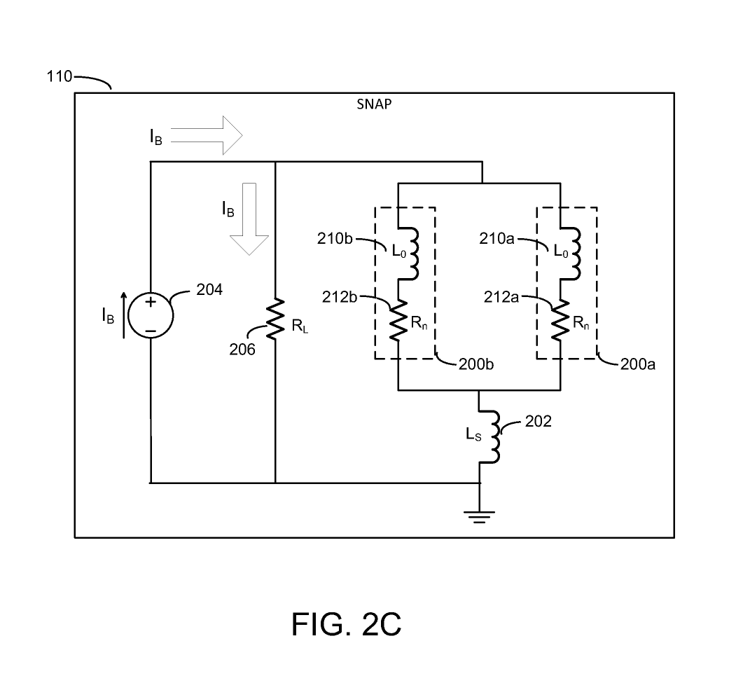

In some cases, the plurality of elongated, substantially equally spaced portions of the electrically superconductive material can be substantially parallel. The plurality of elongated portions can be arranged, in some embodiments, in a side-by-side manner (i.e., a straight line perpendicular to the lengths and/or tangents of the elongated portions intersects each of the plurality of elongated portions). An example is illustrated in FIG. 2A. The plurality of elongated portions can be connected by portions of electrically superconductive material proximate the ends of the elongated portions to form a serpentine nanowire. The serpentine nanowire can include a regularly repeating pattern of turns that form multiple portions (which can be substantially parallel) spaced at a regular interval.

While FIG. 2A illustrates a possible embodiment in which a single nanowire is formed in a serpentine pattern, it should be understood that other patterns can be formed. For example, a plurality of nanowires can be formed. In some embodiments, a plurality of nanowires, not monolithically integrally with each other (i.e., connected via the same electrically superconductive material during a single formation step), can be formed as a series of substantially parallel nanowires arranged in a side-by-side manner. In such cases, the nanowires can be connected, in series or in parallel, using a different electrically superconductive material (e.g., formed on the substrate), an electrically conductive material (e.g., metals such as gold, silver, aluminum, titanium, or a combination of two or more of these which can be, for example, formed on the substrate), and/or using a off-substrate circuitry. In cases where multiple substantially parallel nanowires are used, the period of the plurality of nanowires is defined in a similar fashion as described above with relation to the serpentine nanowire.

In still other embodiments, the plurality of elongated, substantially equally spaced portions of electrically superconductive material can include one or more curves. For example, the plurality of elongated, substantially equally spaced portions can be substantially concentric, in some cases. In some embodiments, portions of the nanowire may be formed in the shape of a spiral.

In some embodiments, the nanowire (or plurality of nanowires) can include a relatively large period. For example, the period between elongated substantially equally spaced portions of the nanowire can be at least about 250 nm, at least about 500 nm, at least about 600 nm, between about 250 nm and about 800 nm, between about 500 nm and about 700 nm, or between about 550 nm and about 650 nm, in some embodiments. In some cases, the period can depend on the index of refraction of the substrate material and/or the wavelength of electromagnetic radiation to which the detector is designed to be exposed. For example, as the wavelength (as measured in a vacuum) of the detected electromagnetic radiation is increased, it can be desirable to increase the period. In some cases, as the index of refraction of the substrate material is increased, it may be desirable to decrease the period. In some embodiments, the period of substantially equally spaced portions of the nanowire can be between about 0.45(λ/n) and about 0.9(λ/n), between about 0.55(λ/n) and about 0.8(λ/n), between about 0.60(λ/n) and about 0.75(λ/n), or between about 0.66(λ/n) and about 0.69(λ/n), wherein λ is the wavelength of electromagnetic radiation (as measured in a vacuum) to which the detector is constructed and arranged to be exposed, and n is the index of refraction of the substrate material. Nanowires with relatively large periods can be useful in forming photon detectors with relatively large surface areas, while maintaining reasonable efficiencies and speeds.

The photon detectors described herein can be constructed and arranged to detect wavelengths of electromagnetic radiation that fall within specified ranges. For example, in some cases, a photon detector can be constructed and arranged to detect infrared electromagnetic radiation (e.g., infrared electromagnetic radiation with a wavelength between about 750 nm and about 10 micrometers, as measured in a vacuum). In some cases, the photon detector can be constructed and arranged to detect visible light (i.e., wavelengths of between about 380 nm and about 750 nm, as measured in a vacuum). In some cases, the photon detector can be constructed and arranged such that, during operation, it can be tuned to detect a predetermined range of wavelengths of electromagnetic radiation (e.g., a range with a width of less than about 1000 nm, less than about 100 nm, less than about 10 nm, between about 0.1 nm and about 1000 nm, between about 0.1 nm and about 100 nm, between about 0.1 nm and about 10 nm, or between about 0.1 nm and about 1 nm, each range as measured in a vacuum).

The photon detectors described herein can have various sizes of active areas. In some embodiments, a photon detector can have an active area of at least about 9 square microns, at least about 25 square microns, at least about 75 square microns, at least about 150 square microns, between about 9 square microns and about 250 square microns, or between about 9 square microns and about 100 square microns.

A variety of materials and methods can be used to form articles (e.g., photon detectors) and systems described herein. In some cases, one or more components can be formed using MEMS-based microfabrication techniques. For example, various components can be formed from solid materials, in which various features (e.g., nanowires, gratings of electrically conductive material, layers of electrically insulating material, and the like) can be formed via micromachining, film deposition processes such as spin coating and chemical vapor deposition, laser fabrication, photolithographic techniques, etching methods including wet chemical or plasma processes, and the like.

One of ordinary skill in the art would understand how to connect the devices described herein to external devices (e.g., an RF coaxial readout, a lens coupled fiber, etc.) for use in practice. For example, electrical contacts can be made to the electrically superconductive material (e.g., the electrically superconductive nanowire) by fabricating electrically conductive contact pads connected to the ends of the electrically superconductive material. In some embodiments, the devices (e.g., photon detectors) described herein can be constructed and arranged to be used at very low temperatures (e.g., less than about 10 K, less than about 5 K, or less than about 3 K). One of ordinary skill in the art would be capable of designing the systems and articles described herein such that stable electrical communication could be made at these very low temperatures.

The terms “electrically insulating material,” “electrically conductive material,” and “semiconductor material” would be understood by those of ordinary skill in the art. In addition, one of ordinary skill in the art, given the present disclosure, would be capable of selecting materials that fall within these categories while providing the necessary function to produce the devices and performances described herein. For example, one of ordinary skill in the art would be capable of selecting a material that would be capable of providing proper electrical insulation between an electrically superconductive material and a relatively electrically conducting material in order to, for example, prevent electron transfer between those two materials. In some embodiments, an electrically conductive material can have an electrical resistivity of less than about 10⁻³ ohm.cm at 20° C. The electrically insulating material can have, in some instances, an electrical resistivity of greater than about 10⁸ ohm.cm at 20° C. In some instances, a semiconductor material can have an electrical resistivity of between about 10⁻³ and about 10⁸ ohm.cm at 20° C.

The thermal relaxation time τₜ of a nanowire, such as a SNSPD, may be a factor in determining how quickly the detector can count photons. The thermal relaxation time τₜ of a nanowire may depend on the nominal inductance, L₀ of the nanowire. The nominal inductance L₀ of a nanowire may be a nominal inductance that represents various inductive sources within the nanowire. For example, the nominal inductance may include kinetic inductance, which is the inductance related to stored energy in the kinetic motion of charge carriers. Other factors such as magnetic flux around the nanowire may alternatively or additionally impact its nominal inductance.

In the examples described herein, the nominal inductance for each nanowire in a SNAP is assumed to be the same. In some embodiments, there may be variations form wire-to-wire such that different nanowires, though regarded as having the same nominal inductance, may have different actual inductances. In some embodiments, for example, the nominal inductance may represent an average over the nanowires in a SNAP. The actual inductance of a particular nanowire may differ from the nominal inductance. For example, the actual inductance of nanowire may be within +/−20% of the nominal value L₀. However, it should be appreciated that the actual inductance may have greater variation. For example, if the nominal inductance is an average of different nanowire inductances, then the actual inductance may vary by more than +/−20% from the nominal value L₀. For example, the actual inductance may vary by as much as +/−40%, or +/−60%, depending on the specific nature of the nanowires.

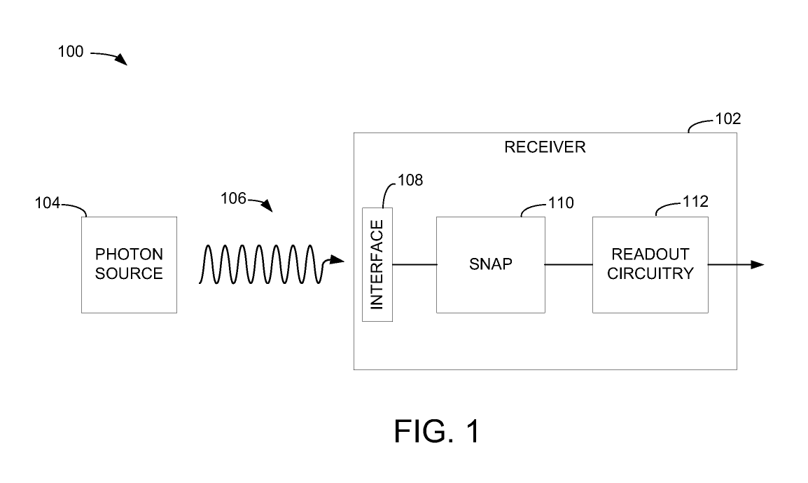

FIG. 1 is a schematic illustration of an exemplary optical communication system 100, in accordance with some embodiments. An optical receiver 102 may be configured to receive signals from a photon source 104. The photon source 104 may be any suitable source of photons, such those used in optical transmitters in fiber optics or free-space optics. Though, it should be appreciated that the photon source 104 need not be a mechanical transmitter, and may be an object which is to be imaged, for example by a camera or detector, as is known in fields such as astronomy or photography.

The photon source 104 may emit photons which travel through an optical communication medium 106. The nature of the photon source 104 is not critical to the invention, and photons emitted by the source 104 may have any suitable frequency. For example, sensitive detectors as described herein may be used to detect photons in the infrared range or higher frequency photons.

The optical communication medium 106 may be a component that guides the photons. Examples of such a medium include a fiber, waveguide, or a coupler. Alternatively, in some embodiments, the optical communication medium 106 may be free space. Regardless of the exact nature of the photon source 104 and the optical communication medium 106, the optical receiver 102 may receive one or more photons at different times.

The reception of photons may, in some embodiments, be performed via an interface 108. The interface may allow coupling between the receiver 102 and the optical communication medium 106, which may be a fiber optic cable or a waveguide. Alternatively or additionally, the interface 108 may comprise lenses or other components that facilitate reception of photons from the communication medium 106 and coupling them to photon detection system 110.

A photon detection system, such as a SNAP 110, may be configured to detect the arrival of photons. The SNAP 110 may comprise at least two low-temperature nanowires coupled in parallel. Under certain conditions, the nanowires may provide amplification for an electrical pulse generated by a photon absorption. Such an electrical signal may be read out by readout circuitry 112. The readout circuitry may comprise low-temperature or room-temperature electronics, as is known in the art, configured to detect pulses of electrical energy emitted from the SNAP 110.

FIG. 2A is a schematic illustration of an exemplary configuration of a SNAP 110. In this example, two nanowires are illustrated, 200a and 200b. It should be appreciated that two nanowires are shown for simplicity. Any suitable number of nanowires may be used in a SNAP 110. In some embodiments, the nanowires 200a and 200b may be superconducting nanowires. The superconducting nanowires may be configured to be highly sensitive. For example, in some embodiments, the nanowires may be SNSPDs, as is known in the art.

In the example shown in FIG. 2A, the nanowires 200a and 200b may be coupled in parallel to each other. The parallel nanowires 200a and 200b may also be coupled in series with an inductive element 202, having an inductance value L_{S}. The inductive element 202 may also be configured as a nanowire, which may be but need not be superconducting, although it should be appreciated that any suitable configuration for inductive element 202 may be used.

In some embodiments, a DC bias source 204 may be configured to provide a steady-state current I_{B} through the SNAP 110. In some embodiments, a load resistance 206 having resistance R_{L} may be coupled in parallel to the nanowires 200a and 200b, the inductive element 202, and the DC bias source 204. The load resistance R_{L} may be any suitable value to enable correct operation of the SNAP. In some embodiments, R_{L} may have a value between 25 and 100 Ohms. Though, in some embodiments, R_{L} may be between 40 Ohms and 60 Ohms. As a specific example, R_{L} may be 50 Ohms. Regardless of the exact value of R_{L}, the load resistance 206 may be used to read out electrical pulses emitted from the nanowires 200a and 200b, in response to photon absorption events.

If the bias current I_{B} is configured such that the nanowires 200a and 200b are each superconducting in steady-state, then substantially all of the bias current I_{B} may pass through the nanowires 200a and 200b, with negligible current passing through the load resistor 206. As a result, the entire bias current I_{B} may be split between the two nanowires 200a and 200b, for example, each nanowire having a current I_{B}/N, with N being equal to 2 in this example.

FIG. 2B is a schematic illustration of an example of a SNAP 110 that has absorbed a photon and begun a first stage of an amplification process. In this example, an equivalent circuit model is illustrated for the nanowires 200a and 200b. In some embodiments, each of the nanowires 200a and 200b may have a nominal inductance L₀, modeled by inductors 210a and 210b, respectively. Though, it should be appreciated that the actual inductances of the nanowires may differ, and techniques described herein may also be used for SNAPs having nanowires with unequal inductances.

For certain values of bias current I_{B}, an incident photon 208 may cause the first nanowire 200a to absorb enough energy to lose its superconductivity and temporarily become highly resistive. This temporary resistance is modeled by a series resistor 212a with value Rₙ. In some embodiments, the value of Rₙ may be large enough to substantially block all of the current passing through nanowire 200a. This may result in the current that passed through nanowire 200a to be shunted away to the second nanowire 200b, which may still be in a superconducting state.

For certain values of bias current I_{B}, the increased current through the second nanowire 200b may also drive the second nanowire 200b above its superconducting threshold, resulting in a second stage of amplification.

FIG. 2C is a schematic illustration of an example of a SNAP 110 that has begun a second stage of amplification. In FIG. 2C, following a photon absorption and a transition out of superconductivity by the first nanowire 200a, the second nanowire 200b may also transition out of its superconductive state and temporarily become highly resistive. This temporary resistance is modeled by a resistance 212b. As with the first nanowire 200a, the highly-resistive second nanowire 200b may block substantially all of the current that passed through it. As a result, the full bias current I_{B} may be shunted through the load resistor 206, resulting in an output voltage pulse.

After some time delay, the nanowires 200a and 200b may become superconducting again, and the SNAP 110 may return to the steady state illustrated in FIG. 2A, ready for another photon detection. However, if a photon arrives during this “cooling” period, while the nanowires are still in a non-superconducting state, then the SNAP 110 may be desensitized to the photon's arrival. As such, the photon may go undetected at the output load resistor 206, resulting in reduced detection efficiency for the SNAP 100.

As illustrated in FIGS. 2A-2C, the multi-stage amplification process of a SNAP may result in a larger total output current flowing through resistor 206 in response to an incident photon, as compared to a single nanowire. Since each nanowire is limited in the amount of current it can support before losing superconductivity, the amount of current that it can divert to the output is also limited. By using multiple stages of nanowires, the individual currents diverted from each nanowire may be superimposed to provide a larger aggregate output current at the output load resistor.

In order to achieve such multi-stage amplification, the bias current I_{B} may be configured with some bias margin. The bias margin may be the difference between two current levels. The upper current level may be a SNAP switching current, I_{SW}, above which all the nanowires may be biased out of superconductivity in steady-state. In such regimes, none of the nanowires may be able to detect a photon arrival. In an N-SNAP, the switching current I_{SW} may correspond to N times the individual superconducting critical current threshold for a single nanowire.

The lower current level may be the avalanche current, I_{AV}, equal to the minimum bias current necessary to activate a second nanowire upon photon absorption by a first nanowire. The bias margin may correspond to the gap between the avalanche current, I_{AV}, and a SNAP switching current, I_{SW}:

$$B = \frac{{I}_{S W} - {I}_{A V}}{{I}_{S W}} \qquad ( 1 )$$

The inventors have recognized and appreciated that the bias margin B depends on the series inductance L_{S}, through the avalanche current, I_{AV}. The avalanche current may depend on L_{S} because small series inductance may result in more leakage current, which may require larger bias current to maintain the nanowires close to their individual superconducting critical current thresholds. In some embodiments, the avalanche current I_{AV}, in proportion to the SNAP switching current I_{SW}, may be approximated by the following function of L_{S}:

$$\frac{{I}_{A V}}{{I}_{S W}} ≅ 1 - \frac{{L}_{S}}{{L}_{0} + {L}_{S} N} \qquad ( 2 )$$

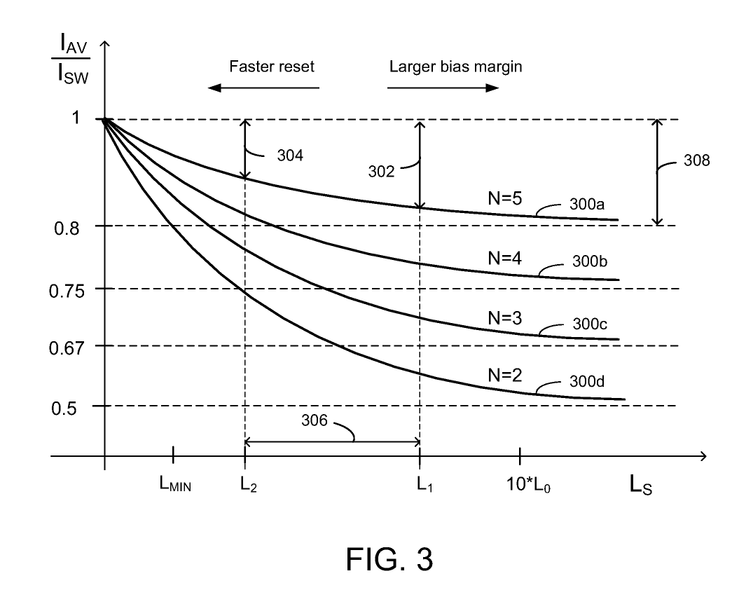

FIG. 3 illustrates a graphical sketch of the ratio of avalanche current to SNAP switching current, I_{AV}/I_{SW}, as a function of series inductance L_{S} for different values of the number N of parallel nanowires. In FIG. 3, the horizontal axis represents the series inductance L_{S}. Illustrated are four different curves, 300a, 300b, 300c, 300d, depicting I_{AV}/I_{SW} in Equation (2) for N=5, 4, 3, 2, respectively (where N is the number of parallel nanowires in the SNAP).

In this example, the curves 300a, 300b, 300c, 300d are lower-bounded by a sequence of horizontal lines at values 0.8, 0.75, 0.67, and 0.5, respectively. These lower bounds represent a “no leakage” scenario for each value of N. In such “no leakage” scenarios (also referred to as “perfect redistribution” scenarios), it is assumed that substantially all of a photon-induced current pulse is trapped by a large Ls, and is redistributed to the other N-1 nanowires.

The top-most horizontal line represents the SNAP switching current, Isw. Above this level, the bias current is strong enough to force all N nanowires into their non-superconducting states in steady state, and therefore unable to detect photons. To enable correct operation of a SNAP, the bias current may be configured to be below the SNAP switching current Isw.

The vertical gap between the SNAP switching current I_{AV}=Isw and each curve 300a, 300b, 300c, 300d represents the bias margin for the corresponding value of N. In FIG. 3, two different bias margins, 302 and 304, are labeled for the curve 300a (corresponding to N=5). The inventors have recognized and appreciated that the bias margin of a SNAP increases with increasing series inductance L_{S}. For example, in FIG. 3, bias margin 302, corresponding to a series inductance value of L₁, is larger than bias margin 304 at a larger value L₂ of series inductance.

However, the inventors have also recognized and appreciated that larger bias margin may come at a price of increased SNAP reset time T_{R}, and thus decreased efficiency. In some embodiments, this tradeoff between bias margin and SNAP reset time T_{R} may be used to improve the design of a SNAP. For example, if a desired value of bias margin is known, then a minimum value of SNAP reset time may be achieved by appropriately selecting a value for the series inductance L_{S} in a SNAP. Alternatively, if a desired value of reset time is known, then a value for the series inductance L_{S} may be selected to maximize the bias margin.

For example, in FIG. 3, the upper inductance value L₁ may correspond to a desired maximum SNAP reset time (minimum efficiency), while the lower inductance value L₂ may correspond to a desired minimum bias margin. The actual series inductance L_{S} may then be configured to be anywhere within the range 306 between L₁ and L₂. For example, to achieve greatest bias margin under these constraints, the series inductance may be chosen to be L₁. To achieve smallest SNAP reset time, the series inductance may be chosen to be L₂.

As a specific example, for a given desired bias margin B, the corresponding series inductance may be approximately computed using the expression:

$${L}_{B} = \frac{B {L}_{0}}{1 - B N} \qquad ( 3 )$$

In some embodiments, Equation (3) may provide a lower bound on the allowable values of series inductance L_{S} that achieve a bias margin of at least B. By setting L_{S} equal to L_{B} (so that the bias margin is exactly equal to B), minimum reset time can be approximately achieved for a bias margin of B.

Alternatively, for a given desired SNAP reset time T_{R}, the corresponding series inductance may be approximately computed using the expression:

$${L}_{{T}_{R}} = \frac{{T}_{R} {R}_{L}}{3} - \frac{{L}_{0}}{N} \qquad ( 4 )$$

In some embodiments, Equation (4) may provide an upper bound on the allowable values of series inductance L_{S} that achieve a rest time of at most T_{R}. By setting L_{S} equal to L_{TR} (so that the reset time is exactly equal to T_{R}), maximum bias margin can be approximately achieved for a reset time of T_{R}.

The tradeoff between reset time and bias margin may be used to determine upper and lower bounds on the value of series inductance L_{S} that enables a systematic approach to improving the performance of the SNAP. In some embodiments, the series inductance may be configured to be less than 10*L₀, or 10 times the nominal inductance of each nanowire.

The inventors have further recognized and appreciated that, in addition to user-defined target performance parameters, in some embodiments, the series inductance L_{S} may have lower bounds, such as L_{MIN}, that are due to intrinsic limitations of the SNAP. For example, in some embodiments, it may be desirable to configure the SNAP reset time T_{R} to be greater than the thermal relaxation time tiₜ of the individual nanowires. Otherwise, the nanowires may not have enough time to sufficiently “cool down” after a photon absorption event. As a result, when the bias current, diverted to the output resistor in response to a photon, redistributes back to the nanowires, the nanowires may once again be pushed back to non-superconducting state, resulting in spurious output pulses. As a result, multiple output pulses may be emitted for a single photon detection, reducing detection accuracy and rendering difficult a determination of efficiency.

Some specific examples of these tradeoffs and limits are provided next. In FIG. 3, for N=5, the bias margin 302 may be desired to be at least 70% of the maximum bias margin 308. The corresponding value of L₁ may be computed using Equation (3) to be approximately (7/3)*(L₀/N). The series inductance L_{S} may then be configured to be at least L₁, with equality achieving the smallest possible reset time for the 70% bias margin constraint.

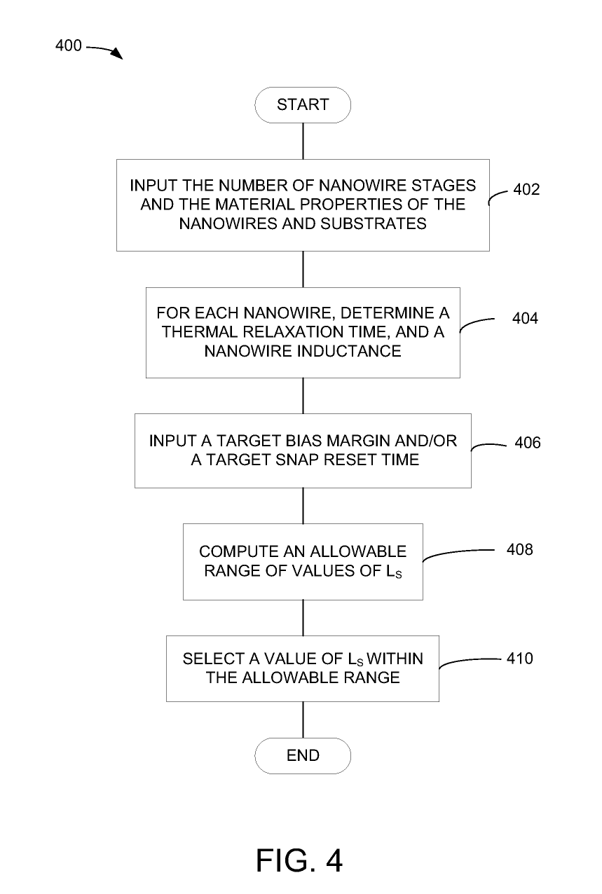

As another example, if the nanowire thermal relaxation time is τₜ, then the minimum inductance L_{MIN} in FIG. 4 may be computed using Equation (4) to be approximately (τₜ/3)*R_{L}−(L₀/N). This may provide another lower bound on the series inductance L_{S}. For example, in the 70% bias margin constraint described above, the series inductance L_{S} may be configured to be greater than both (τₜ/3)*R_{L}−(L₀/N) and (7/3)*(L₀/N).

In general, the tradeoff between SNAP reset time and bias margin may be used to configure the series inductance L_{S}, for example, by using Equations (3) and (4), so that the SNAP can achieve close approximately optimal performance for a given set of performance parameters.

FIG. 4 is a flow chart of an exemplary method 400 of designing a SNAP, in accordance with some embodiments. Such a method may be implemented, for example, by a computing device used as a design tool for configuring the SNAP based on user inputs indicating desired values of parameters, such as reset time and/or bias margin.

In step 402, one or more user input parameters may be received for the SNAP design, such as the number N of nanowires, the dimensions of each nanowire, and the material properties of the nanowires and substrate. For example, the number N of nanowires in a SNAP may be any suitable number. In some embodiments, the number N may be 2, 3, 4, or 5. Based on the material properties and dimensions of the nanowires, in step 404, various nanowire parameters may be determined, such as the thermal relaxation time τₜ, and a nominal inductance L₀ per nanowire.

In step 406, various performance-related inputs may be received from a user, for example, indicating a minimum bias margin and/or a maximum reset time. Based on these input performance parameters, in step 408, an allowable value, or range of values, may be computed for the series inductance L_{S}. Then in step 410, a target value of L_{S} may be selected from within the allowable range. The target value of L_{S} may be selected, for example, to minimize reset time based on a target bias margin, or to maximize bias margin based on a target reset time.

Once a target value of L_{S} is selected a SNAP may be designed to yield that target value. The device may then be fabricated using techniques as are known in the art.

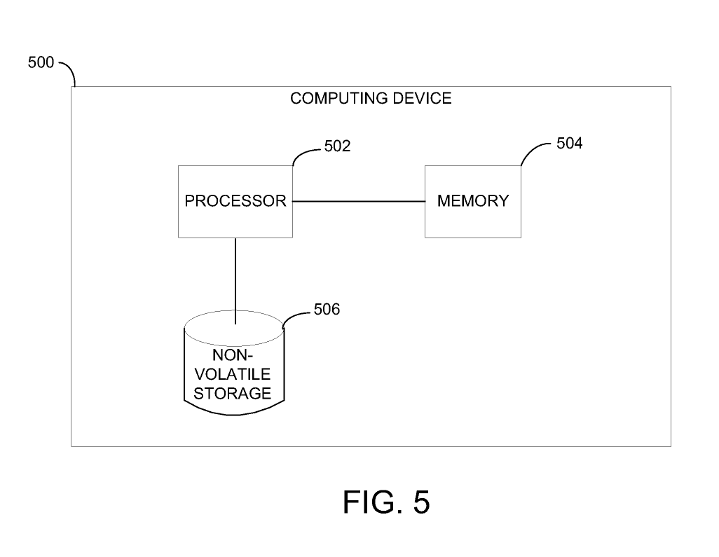

FIG. 5 illustrates an illustrative implementation of a computer system 500 that may be used to implement one or more of the transformation techniques described herein, either to detect an output pulse from the SNAP (e.g., the readout circuitry 112 of FIG. 1) or to design the SNAP configuration (e.g., to implement the method 400 of FIG. 4). Computer system 500 may include one or more processors 502 and one or more non-transitory computer-readable storage media (e.g., memory 504 and one or more non-volatile storage media 506). The processor 502 may control writing data to and reading data from the memory 504 and the non-volatile storage device 506 in any suitable manner, as the aspects of the invention described herein are not limited in this respect. To perform functionality and/or techniques described herein, the processor 502 may execute one or more instructions stored in one or more computer-readable storage media (e.g., the memory 504, storage media, etc.), which may serve as non-transitory computer-readable storage media storing instructions for execution by the processor 502. Computer system 500 may also include any other processor, controller or control unit needed to route data, perform computations, perform I/O functionality, etc.

In connection with the transformation techniques described herein, one or more programs that evaluate data, determine frequency components, and generate digital codes, may be stored on one or more computer-readable storage media of computer system 500. Processor 502 may execute any one or combination of such programs that are available to the processor by being stored locally on computer system 500 or accessible over a network. Any other software, programs or instructions described herein may also be stored and executed by computer system 500. Computer 500 may be a standalone computer, mobile device, etc., and may be connected to a network and capable of accessing resources over the network and/or communicate with one or more other computers connected to the network.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of and ” consisting essentially of shall be closed or semi-closed transitional phrases, respectively, as set forth in the United States Patent Office Manual of Patent Examining Procedures, Section 2111.03.

What is claimed is:

1. A superconducting nanowire avalanche photodetector (SNAP) comprising:
at least two nanowires coupled in parallel, each of the at least two nanowires having a nominal inductance L_{0;} and
an inductive element coupled in series with the at least two nanowires, the inductive element having inductance L_{S},
wherein L_{S} is less than 10*L₀.

2. The SNAP of claim 1, wherein:
the at least two nanowires comprise a number N of nanowires; and
L_{S} is equal to or greater than (7/3)*(L₀/N).

3. The SNAP of claim 1, wherein:
the at least two nanowires comprise a number N of nanowires;
the SNAP further comprises a load resistance having value R_{L} coupled in parallel with the at least two nanowires;
the at least two nanowires have a thermal relaxation time of value τₜ; and
L_{S} is equal to or greater than (τₜ/3)*R_{L}−(L₀/N).

4. The SNAP of claim 1, wherein:
the at least two nanowires comprise a number N of nanowires;
the SNAP further comprises a load resistance having value R_{L} coupled in parallel with the at least two nanowires;
the at least two nanowires have a thermal relaxation time of τₜ; and
L_{S} is equal to or greater than both (τₜ/3)*R_{L}−(L₀/N) and (3/7)*(L₀/N).

5. The SNAP of claim 1, wherein:
the inductance L_{S} is configured such that a SNAP reset time T_{R} is greater than a thermal relaxation time τₜ of the at least two nanowires.

6. The SNAP of claim 5, where:
the SNAP reset time T_{R} comprises a time after a photon detection event at which each of the at least two nanowires substantially recovers full bias current from a DC bias source.

7. The SNAP of claim 2, wherein:
the number N of nanowires is less than or equal to 4.

8. The SNAP of claim 1, wherein:
the minimum inductance is a function of a thermal conductivity of the at least two nanowires.

9. The SNAP of claim 1, further comprising:
at least one DC bias source coupled to each of the at least two nanowires.

10. The SNAP of claim 9, wherein:
the DC bias source is configured to provide a current based on the inductance L_{S}, wherein
the current provided by the DC bias source is larger for smaller values of L_{S}.

11. The SNAP of claim 1, wherein:
the at least two nanowires comprise niobium (Nb) and is configured to have a width narrower than 100 nm and a thickness between 4 nm and 6 nm.

12. The SNAP of claim 1, wherein:
the at least two nanowires are configured in a serpentine pattern.

13. The SNAP of claim 1, wherein:
the at least two nanowires comprise a superconducting nanowire single-photon detector (SNSPD).

14. The SNAP of claim 1, wherein:
the at least two nanowires is constructed and arranged to detect a photon of at least one frequency equal to or greater than a frequency of infrared electromagnetic radiation.

15. The SNAP of claim 1, wherein:
the at least two nanowires are constructed and arranged to detect a photon of at least one frequency of microwave electromagnetic radiation.

16. The SNAP of claim 1, wherein:
the inductive element comprises a nanowire.

17. The SNAP of claim 1 in combination with components comprising a communication system, the components comprising the communication system comprising an interface to an optical communication medium, the interface configured to couple photons from a communications medium to the SNAP.

18. A method of designing a superconducting nanowire avalanche photodetector (SNAP), the method comprising:
receiving inputs comprising values indicating a number N of at least two nanowires to be coupled in parallel and a nominal inductance L₀ of at least one of the at least two nanowires;
computing a value L_{S} of an inductive element to be coupled in series with the at least two nanowires, wherein:
computing the value L_{S} is based on the number N of nanowires and the nominal inductance L₀; and
L_{S} is less than or equal to 10*L₀.

19. The method of claim 18, further comprising:
determining a maximum reset time and/or a minimum reset time of the SNAP;
determining a maximum inductance based on the maximum reset time and/or determining a minimum inductance based on the minimum reset time, and
wherein computing the value L_{S} of the inductive element comprises computing a value L_{S} less than the determined maximum inductance and/or greater than the determined minimum inductance.

20. The method of claim 19, wherein:
determining a maximum inductance based on the maximum reset time and/or determining a minimum inductance based on the minimum reset time comprises using the equation (T_{R}*R_{L}/3)−(L₀/N),
wherein T_{R} is a value of a SNAP reset time and R_{L} is a value of a load resistance to be coupled in parallel with the at least two nanowires.

21. The method of claim 20, wherein:
the minimum reset time is equal to a value τₜ of a thermal relaxation time of the at least two nanowires; and
determining a minimum inductance based on the minimum reset time comprises using the equation (τₜ*R_{L}/3)−(L₀/N).

22. The method of claim 18, further comprising:
determining a minimum bias margin;
determining a minimum inductance based on the minimum bias margin, and
wherein computing the value L_{S} of the inductive element comprises computing a value L_{S} greater than the determined minimum inductance.

23. The method of claim 22, wherein:
determining the minimum inductance based on the minimum bias margin comprises using the equation (B*L₀)/(1−B*N), wherein B is a value of a bias margin.

24. The method of claim 22, wherein:
the minimum bias margin is equal to 0.7/N; and
determining the minimum inductance comprises using the equation (7/3)*(L₀/N).

25. The method of claim 18, further comprising:
determining a value R_{L} of a load resistance to be coupled in parallel with the at least two nanowires; and
determining a value τₜ of a thermal relaxation time of the at least two nanowires,
wherein computing the inductance L_{S} further comprises computing a value of L_{S} greater than both (τₜ/3)*R_{L}−(L₀/N) and (7/3)*(L₀/N).

26. The method of claim 18, wherein:
the number N of the at least two nanowires is less than or equal to 5.

27. The method of claim 18, wherein:
the inductance L_{S} is configured such that a SNAP reset time T_{R} is greater than a thermal relaxation time of the at least two nanowires.

28. The method of claim 19, wherein:
the SNAP reset time T_{R} comprises a time after a photon detection event at which each of the at least two nanowires substantially recovers full bias current from a DC source.

29. The method of claim 18, further comprising:
determining a value of a DC bias current based on the inductance L_{S},
wherein the determined value of the DC bias current is larger for smaller values of L_{S}.

30. The method of claim 18, wherein:
the at least two nanowires comprises a superconducting nanowire single-photon detector (SNSPD).

31. At least one computer-readable storage medium comprising computer executable instructions that, when executed by a computing device, perform a method of designing a superconducting nanowire avalanche photodetector (SNAP), the method comprising:
receiving inputs comprising values indicating a number N of at least two nanowires to be coupled in parallel and a nominal inductance L₀ of the at least two nanowires;
computing a value L_{S} of an inductive element to be coupled in series with the at least two nanowires, wherein:
computing the value L_{S} is based on the number N of the at least two nanowires and the nominal inductance L₀; and
L_{S} is less than or equal to 10*L₀.

32. The at least one computer-readable storage medium of claim 31, wherein the method further comprises:
determining a maximum reset time and/or a minimum reset time of the SNAP;
determining a maximum inductance based on the maximum reset time and/or determining a minimum inductance based on the minimum reset time, and
wherein computing the value L_{S} of the inductive element comprises computing a value L_{S} less than the determined maximum inductance and/or greater than the determined minimum inductance.

33. The at least one computer-readable storage medium of claim 32, wherein:
determining a maximum inductance based on the maximum reset time and/or determining a minimum inductance based on the minimum reset time comprises using the equation (T_{R}*R_{L}/3)−(L₀/N),
wherein T_{R} is a value of a SNAP reset time and R_{L} is a value of a load resistance to be coupled in parallel with the at least two nanowires.

34. The at least one computer-readable storage medium of claim 33, wherein:
the minimum reset time is equal to a value τₜ of a thermal relaxation time of the at least two nanowires; and
determining a minimum inductance based on the minimum reset time comprises using the equation (τₜ*R_{L}/3)−(L₀/N).

35. The at least one computer-readable storage medium of claim 31, wherein the method further comprises:
determining a minimum bias margin;
determining a minimum inductance based on the minimum bias margin, and
wherein computing the value L_{S} of the inductive element comprises computing a value L_{S} greater than the determined minimum inductance.

36. The at least one computer-readable storage medium of claim 35, wherein:
determining the minimum inductance based on the minimum bias margin comprises using the equation (B*L₀)/(1−B*N), wherein B is a value of a bias margin.

37. The at least one computer-readable storage medium of claim 35, wherein:
the minimum bias margin is equal to 0.7/N; and
determining the minimum inductance comprises using the equation (7/3)*(L₀/N).

38. The at least one computer-readable storage medium of claim 31, wherein the method further comprises:
determining a value R_{L} of a load resistance to be coupled in parallel with the at least two nanowires; and
determining a value τₜ of a thermal relaxation time of the at least two nanowires,
wherein computing the inductance L_{S} further comprises computing a value of L_{S} greater than both (τₜ/3)*R_{L}−(L₀/N) and (7/3)*(L₀/N).

39. The at least one computer-readable storage medium of claim 31, wherein:
the number N of the at least two nanowires is less than or equal to 5.

40. The at least one computer-readable storage medium of claim 31, wherein:
the inductance L_{S} is configured such that a SNAP reset time T_{R} is greater than a thermal relaxation time tₜ of the at least two nanowires.

41. The at least one computer-readable storage medium of claim 32, wherein:
the SNAP reset time T_{R} comprises a time after a photon detection event at which each of the at least two nanowires substantially recovers full bias current from a DC source.

42. The at least one computer-readable storage medium of claim 31, wherein the method further comprises:
determining a value of a DC bias current based on the inductance L_{S},
wherein the determined value of the DC bias current is larger for smaller values of L_{S}.

43. The at least one computer-readable storage medium of claim 31, wherein:
the at least two nanowires comprise a superconducting nanowire single-photon detector (SNSPD).
